(19) United States
(12) Patent Application Publication
(10) Pub. No.: US 2014/0054614 A1
(43) Pub. Date: Feb. 27, 2014

(54) SEMICONDUCTOR DEVICE HAVING OPTICALLY-COUPLED ELEMENT

(71) Applicant: KABUSHIKI KAISHA TOSHIBA, Tokyo (JP)

(72) Inventors: Hidetomo TANAKA, Fukuoka-ken (JP); Isao OGAWA, Ooita-ken (JP); Yuta KUGIYAMA, Fukuoka-ken (JP); Hiroaki OOHIRA, Fukuoka-ken (JP)

(73) Assignee: KABUSHIKI KAISHA TOSHIBA, Tokyo (JP)

(21) Appl. No.: 13/778,844

(22) Filed: Feb. 27, 2013

(30) Foreign Application Priority Data
Aug. 21, 2012 (JP) 2012-182214

(51) Int. Cl. H01L 31/16

(52) U.S. Cl. CPC H01L 31/16
USPC 257/82

(57) ABSTRACT

According to one embodiment, a semiconductor device includes a light-emitting element, a light-receiving element, a primary side lead electrically connected to the light-emitting element, a secondary side lead electrically connected to the light-receiving element and a molded body. The molded body includes an internal resin, an external resin and a light shielding layer. The internal resin covers a portion fixed with the light-emitting element of the primary side lead and a portion fixed with the light-receiving element of the secondary side lead. The external resin covers the internal resin, and shields external light to which the light-receiving element is sensitive. The light shielding layer is provided at a position closer to the second surface than any of the light-emitting element, the light-receiving element, the primary side lead, and the secondary side lead, and shielding the external light.

### CROSS REFERENCE TO RELATED APPLICATION

This application is based upon and claims the benefit of priority from the prior Japanese Patent Application No. 2012-182214, filed on Aug. 21, 2012, the entire contents of which are incorporated herein by reference.

### FIELD

Embodiments described herein relate generally to a semiconductor device.

### BACKGROUND

It is required to reduce the sizes of semiconductor devices, but, in a photocoupler including a light-emitting element and a light-receiving element which are housed in the same package, for example, a space to ensure withstand voltage between an input side (a primary side) and an output side (a secondary side) is required. More specifically, it is necessary to provide a gap, which is equal to or more than a certain level, between the light-emitting element and the light-receiving element. In contrast, a method to reduce the size (making it thinner) by reducing the thickness of a sealing resin is proposed. However, when the thickness of the sealing resin is reduced, shielding of external light becomes insufficient, and the dark current of the light-receiving element increases. Accordingly, the light-receiving sensitivity is degraded, and the reliability of signal transmission may be reduced.

### BRIEF DESCRIPTION OF THE DRAWINGS

FIGS. 1A and 1B are schematic views illustrating a semiconductor device according to a first embodiment;

FIGS. 2A and 2B, FIGS. 3A and 3B are schematic cross-sectional views illustrating steps of manufacturing the semiconductor device in sequential order according to the first embodiment;

FIGS. 4A to 4H are schematic views illustrating characteristics of the semiconductor device according to the first embodiment;

FIGS. 5A and 5B are schematic cross-sectional views illustrating a semiconductor device of a modification according to the first embodiment;

FIGS. 6A to 6C are schematic cross-sectional views illustrating a semiconductor device according to a second embodiment;

FIGS. 7A and 7B are schematic cross-sectional views illustrating a semiconductor device of a modification according to the second embodiment;

FIG. 8A is a schematic cross-sectional view illustrating a semiconductor device according to a third embodiment; and

FIG. 8B is a schematic cross-sectional view illustrating a semiconductor device of a comparative example according to the third embodiment.

### DETAILED DESCRIPTION

According to one embodiment, a semiconductor device includes a light-emitting element to emit light, a light-receiving element to detect the light emitted from the light-emitting element, a primary side lead electrically connected to the light-emitting element, a secondary side lead electrically connected to the light-receiving element and a molded body. The molded body covers the light-emitting element, the light-receiving element, a portion of the primary side lead, and a portion of the secondary side lead, and includes a first surface in a same direction as a mounting surface of the primary side lead and a mounting surface of the secondary side lead, and a second surface at a side opposite to the first surface. The molded body includes an internal resin, an external resin and a light shielding layer. The internal resin covers a portion fixed with the light-emitting element of the primary side lead and a portion fixed with the light-receiving element of the secondary side lead. The external resin covers the internal resin, and shields external light to which the light-receiving element is sensitive. The light shielding layer is provided at a position closer to the second surface than any of the light-emitting element, the light-receiving element, the primary side lead, and the secondary side lead, and shields the external light to which the light-receiving element is sensitive.

Hereinafter, embodiments will be described with reference to the drawings. In the drawings, same reference characters denote the same or similar portions.

### First Embodiment

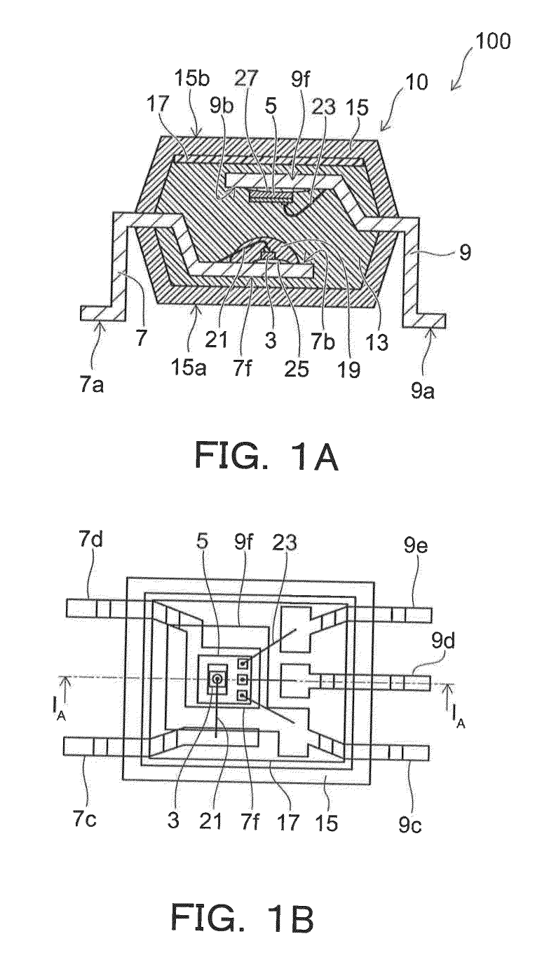

FIGS. 1A and 1B are schematic views illustrating a semiconductor device 100 in accordance with a first embodiment. FIG. 1A illustrates a cross section taken along IA-IA as illustrated in FIG. 1B. FIG. 1B is a perspective view illustrating the semiconductor device 100 which is seen from above.

The semiconductor device 100 is a photocoupler including a light-emitting element 3 and a light-receiving element 5 to detect light of the light-emitting element 3 which are housed in the inside of the resin package (molded body 10).

As illustrated in FIG. 1A, the light-emitting element 3 is fixed (die bonding) onto a mount bed 7f provided at a distal end of a primary side lead (hereinafter, referred to as lead 7) and is electrically connected to the lead 7. The light-receiving element 5 is die-bonded onto a mount bed 9f provided at a distal end of a secondary side lead (hereinafter, referred to as lead 9) and is electrically connected to the lead 9.

More specifically as illustrated in FIG. 1B, the lead 7 includes two leads 7c and 7d disposed apart from each other, for example, and has the mount bed 7f provided at the distal end of the lead 7. The light-emitting element 3 is a light-emitting diode (LED), for example, and is die-bonded onto the mount bed 7f with a conductive paste 25 interposed therebetween. A metal wire 21 is bonded between the light-emitting element 3 and the lead 7c, so that the leads 7c, 7d and the light-emitting element 3 are electrically connected.

On the other hand, the lead 9 includes three leads 9c, 9d, and 9e disposed apart from each other, for example. The mount bed 9f is provided at the distal end of the lead 9c. The light-receiving element 5 is a photodiode with preamp or a phototransistor, for example, and is die-bonded onto the mount bed 9f with an adhesive agent 27 interposed therebetween. Metal wires 23 are respectively bonded between multiple electrodes of the light-receiving element 5 and the leads 9c, 9d, and 9e. Accordingly, the light-receiving element 5 is electrically connected to the leads 9c, 9d, and 9e.

The molded body 10 covers a portion where the light-emitting element 3 is connected which is a portion of the lead 7 and a portion where the light-receiving element 5 is connected which is a portion of the lead 9. The molded body 10 includes an internal resin 13 which is a transparent resin to transmit light emitted from the light-emitting element 3 and an external resin 15 which is a light-shielding resin to shield external light in a wavelength band to which at least the light-receiving element 5 is sensitive. A portion where the light-emitting element 3 is die-bonded and a portion where the light-receiving element 5 is die-bonded are both covered with the internal resin 13.

Portions of the lead 7 and the lead 9 extending from the molded body 10 are bent downward, and are soldered to wirings of a print circuit board when mounted on the print circuit board, for example. More specifically, the semiconductor device 100 is mounted such that a lower surface 15a (first surface) of the molded body 10 faces the print circuit board. The lower surface 15a of the molded body 10 is in the same direction as a mounting surface 7a of the lead 7 and a mounting surface 9a of the lead 9.

In the embodiment, the light-emitting element 3 and the light-receiving element 5 are disposed in the molded body 10 so as to face each other. Preferably, as illustrated in FIG. 1A, the light-emitting surface of the light-emitting element 3 is disposed so as to face the upper side, and the light-receiving surface of the light-receiving element 5 is disposed so as to face the lower side.

The semiconductor device 100 is mounted such that the lower surface 15a of the molded body 10 faces the print circuit board. Therefore, external light to transmit through the external resin 15 and enter into the internal resin 13 is mainly incident from an upper surface 15b (second surface) of the molded body 10. Accordingly, when the light-receiving surface of the light-receiving element 5 faces the lower side, it is possible to suppress increase of a dark current (background level) caused by the external light.

On the other hand, in order to ensure a predetermined withstand voltage between the lead 7 at the primary side in which a signal is input and the lead 9 at the secondary side in which a signal is output, it is desired to widen the space between the light-emitting element 3 and the light-receiving element 5 disposed so as to face each other. More specifically, the thickness of the internal resin 13 in the vertical direction is not to be less than a thickness obtained by adding the thicknesses of the leads 7, 9, the light-emitting element 3, and the light-receiving element 5 and the width of the space between the light-emitting element 3 and the light-receiving element 5. For this reason, the thickness of the external resin 15 to cover the internal resin 13 is reduced, whereby the molded body 10 is made thin, and the height of the semiconductor device 100 can be reduced.

However, when the thickness of the external resin 15 is reduced, the shielding effect of the external light is reduced, and the external light entering into the internal resin 13 increases. Accordingly, in the embodiment, in addition to the arrangement of the light-receiving surface of the light-receiving element 5 facing the lower side, a light shielding layer 17 is provided between the internal resin 13 and the external resin 15. The light shielding layer 17 is provided at the interface of the upper surface side between the internal resin 13 and the external resin 15, and is made of a material of which transmittance of external light to which the light-receiving element 5 is sensitive is less than the transmittance of the external light of the external resin 15. Accordingly, without increasing the thickness of the shielding layer including the light shielding layer 17 and the external resin 15, it is possible to improve the shielding effect of the external light.

The light shielding layer 17 may be made of a metal film such as aluminum, for example, and may be made of a resin in which absorption material or reflection material is dispersed. The light shielding layer 17 disperses the optical absorption material or reflection material with a high degree of density than the external resin 15.

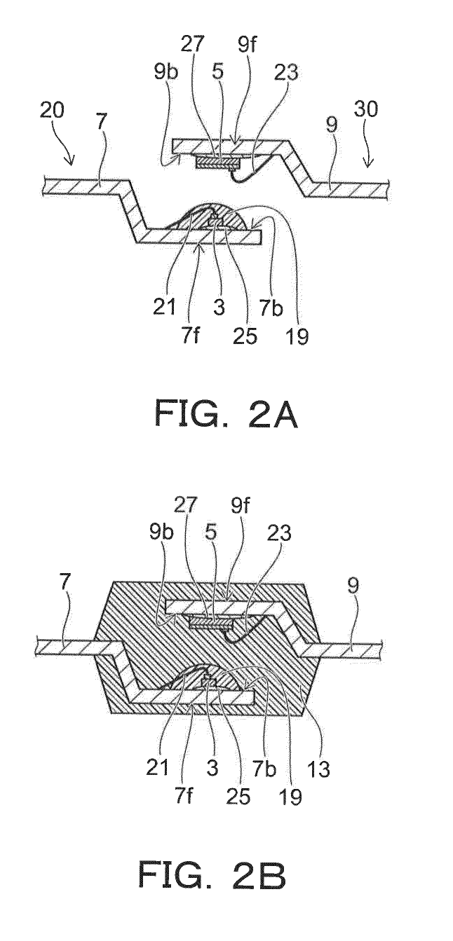

Subsequently, method of manufacturing the semiconductor device 100 will be described with reference to FIGS. 2A to 3B. FIGS. 2A to 3B are schematic cross sectional views illustrating steps of manufacturing the semiconductor device 100.

As illustrated in FIG. 2A, the light-receiving element 5 and the light-emitting element 3 are disposed so as to face each other by combining a lead frame 20 having the light-emitting element 3 mounted at the distal end of the lead 7 and a lead frame 30 having the light-receiving element 5 mounted at the distal end of the lead 9.

The light-emitting element 3 mounted at the distal end of the lead 7 is covered with a transparent encapsulated resin 19, for example. In order to ensure the withstand voltage between the primary side and the secondary side, for example, a gap between an apex of a loop of the metal wire 21 and an apex of a loop of the metal wire 23 is 0.4 mm or more. More specifically, the minimum gap between a conductive body at the primary side and a conductive body at the secondary side is 0.4 mm or more.

As illustrated in FIG. 2B, the internal resin 13 which covers both the distal end portion of the lead 7 mounting the light-emitting element 3 and the distal end portion of the lead 9 mounting the light-receiving element 5, is formed by injection molding method, for example. The internal resin 13 may be made of epoxy resin, acrylic resin, or silicone, for example.

As illustrated in FIG. 3A, the light shielding layer 17 is formed on an upper surface 13b of the internal resin 13. The light shielding layer 17 is a metal film, for example, and is formed by selectively evaporating indium (In) or tin (Sn). A thin film such as aluminum (Al) or copper (Cu) may be pasted. When the metal film is formed with a thickness of several μm, for example, it is possible to shield light in a wavelength band to which the light-receiving element 5 is sensitive such as visible light and infrared light.

The light shielding layer 17 may be made of a resin including a member to absorb or to reflect visible light, infrared light, and the like. In the case, a resin film may be pasted, or application method may be used to form the light shielding layer 17.

As illustrated in FIG. 3B, the external resin 15 to cover the internal resin 13 and the light shielding layer 17 is formed. The external resin 15 may be made of black resin, for example, in which optical absorption material such as carbon is dispersed. Alternatively, white resin in which a reflection material such as titanium oxide is dispersed may be used.

Subsequently, the leads 7 and 9 are cut and separated from the lead frames 20 and 30 after the leads 7, 9 are subjected to bending process. The leads 7, 9 are bent and processed in a direction of the lower surface 15a of the molded body 10, and the mounting surfaces 7a and 9a in the same direction as the lower surface 15a are formed at the distal end portions. Accordingly, the light-receiving element 5 is disposed such that the light-receiving surface of the light-receiving element 5 faces the lower surface 15a, and the light shielding layer 17 is disposed at the side of the upper surface 15b.

The portion where the light shielding layer 17 is provided is the entire upper surface 13b of the internal resin 13 or the portion corresponding to the cross section of the encapsulated resin 19 which is projected above, for example. The size of area of the portion where the light shielding layer 17 is provided is more than the size of area of the portion corresponding to the cross section of the encapsulated resin 19 which is projected above. Further, the thickness of the light shielding layer 17 is preferably the minimum thickness that does not cause peeling after mounted as long as it is a thickness in a range that does not deteriorate the reliability of the semiconductor device 100. For example, in the metal film, the thickness may be about several micron meters. When a resin including the optical absorption material or reflection material is used, it is preferable to increase the amount of resin therein and make the light shielding layer 17 thinner.

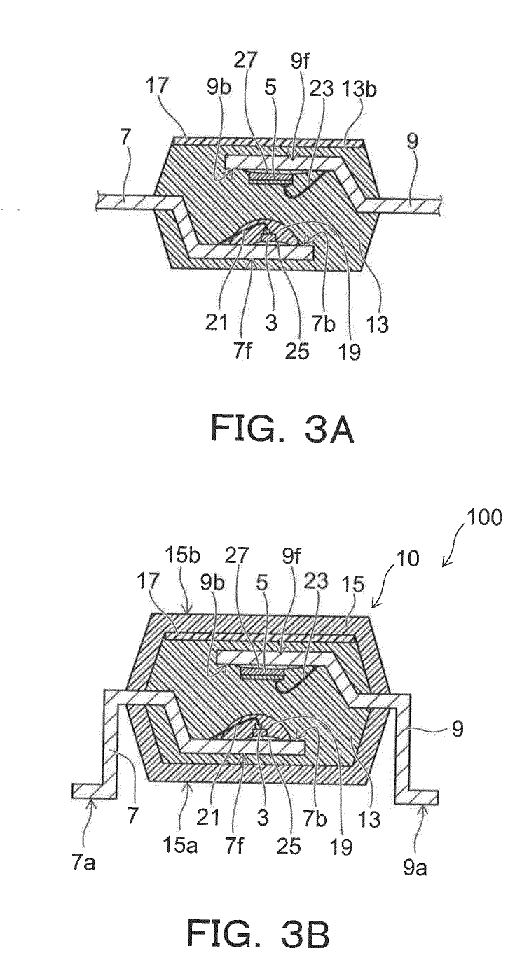

FIGS. 4A to 4H are schematic diagrams representing characteristics of the semiconductor device 100 in accordance with the first embodiment. More specifically, FIGS. 4A to 4H represent relationship between the dark current of the light-receiving element 5 and the position of a light shielding film 50 of aluminum attached to the upper surface 15b of the semiconductor device not provided with the light shielding layer 17.

For example, as illustrated in FIG. 4A, the dark current without the light shielding film 50 is 124.61 nA.

As illustrated in FIGS. 4B to 4D, in a case where optical light-shielding films 50 are attached to the upper and lower sides of the package in the longitudinal, direction, the dark current slightly decreases as compared with FIG. 4A, but does not change greatly.

As illustrated in FIGS. 4E to 4G, in a case where optical light-shielding films 50 are attached to the ends of the package in the lateral direction, the dark current decreases to about 100 nA or less.

Further, as illustrated in FIG. 4H, in a case where a light shielding film 50 is pasted in substantially the center of the upper surface of the package, the dark current decreases to 58.7 nA which is about the half.

The size of the light shielding film 50 used in FIGS. 4B to 4H is about quarter of the size of area of the upper surface of the package, but as described above, the dark current can be greatly reduced. Alternatively, the same effects can also be obtained by selectively evaporating In or Sn using a metal mask and the like. The same effects can also be obtained by forming the internal resin, thereafter forming the light shielding layer 17, and thereafter forming the external resin. Further, concerning the method to form the light shielding layer, the same effects can be obtained no matter which of the application method, the evaporation method, and the adhesion method is employed.

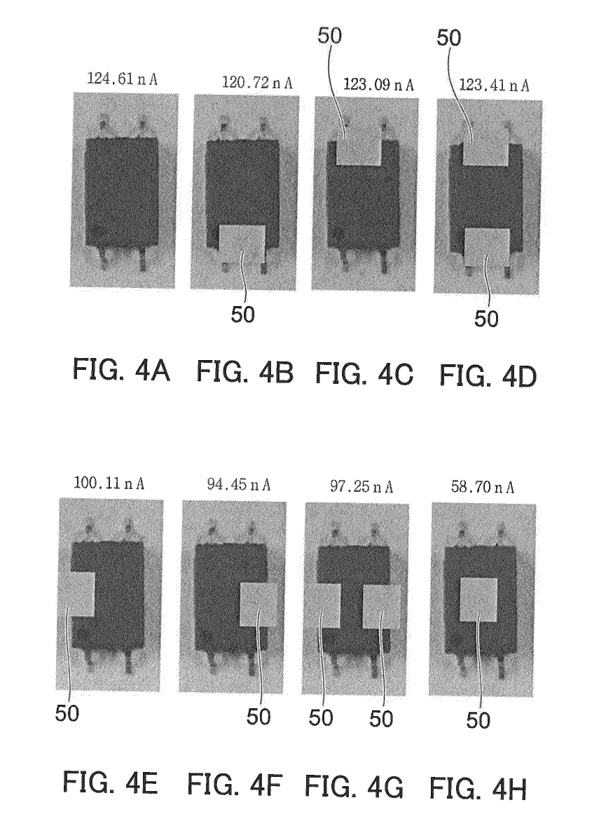

FIGS. 5A and 5B are schematic cross sectional views illustrating a semiconductor device in accordance with a modification of the first embodiment.

In a semiconductor device 200 as illustrated in FIG. 5A, the light shielding layer 17 is provided to be in contact with a back surface 9g of the surface of the lead 9 on which the light-receiving element 5 is mounted. The structure can be achieved by for example, forming the back surface 9g (front surface at the second surface side) of the lead 9 in such a manner that the back surface 9g is exposed when the internal resin 13 is molded. After the internal resin 13 is molded, the portion of the internal resin 13 formed on the back surface 9g of the lead 9 may be removed. Then, after the light shielding layer 17 is formed on the surface of the internal resin 13 where the back surface 9g of the lead 9 is exposed, the external resin 15 is molded. In the case, the thickness of the molded body 10 can be reduced by the thickness of the portion of the internal resin 13 formed on the back surface 9g of the lead 9.

In a semiconductor device 300 as illustrated in FIG. 5B, the light shielding layer 17 is formed on the upper surface 15b of the molded body 10. In this case, a film-shaped light shielding film may be pasted, or may be formed using the application method or the evaporation method. In the modification, after the molded body 10 is formed, the light shielding layer 17 is formed. Accordingly, the light shielding layer 17 does not affect the quality such as the withstand voltage, the strength of package (molded body 10). The modification can be easily performed at a low cost.

In the modifications, the portion where the light shielding layer 17 is formed is preferably the entire upper surface 13b of the internal resin 13, the portion corresponding to the cross section of the encapsulated resin 19 which is projected above, or the portion corresponding to the cross section of the internal resin 13 which is projected above.

As described above, in the embodiment, the shield against the external light can be strengthened by providing the light shielding layer 17. Accordingly the height of the package (molded body 10) can be reduced by reducing the thickness of the external resin 15. In addition, higher degree of sensitivity can be achieved by reducing the dark current of the light-receiving element 5, and therefore, the reliability of the signal transmission can be improved.

For example, when the thickness of the external resin 15 obtained by mixing epoxy resin with fine particles of SiC and alumina is about 0.2 mm, it is possible to ensure a gap distance of 0.4 mm or more between the light-emitting element and the light-receiving element, so that while the withstand voltage between the primary side and the secondary side is maintained, the height of the molded body 10 can be reduced. Therefore, small and highly reliable products can be provided at a low price. By increasing the sensitivity of the light-receiving element 5, the reliability of analog operation can also be improved.

### Second Embodiment

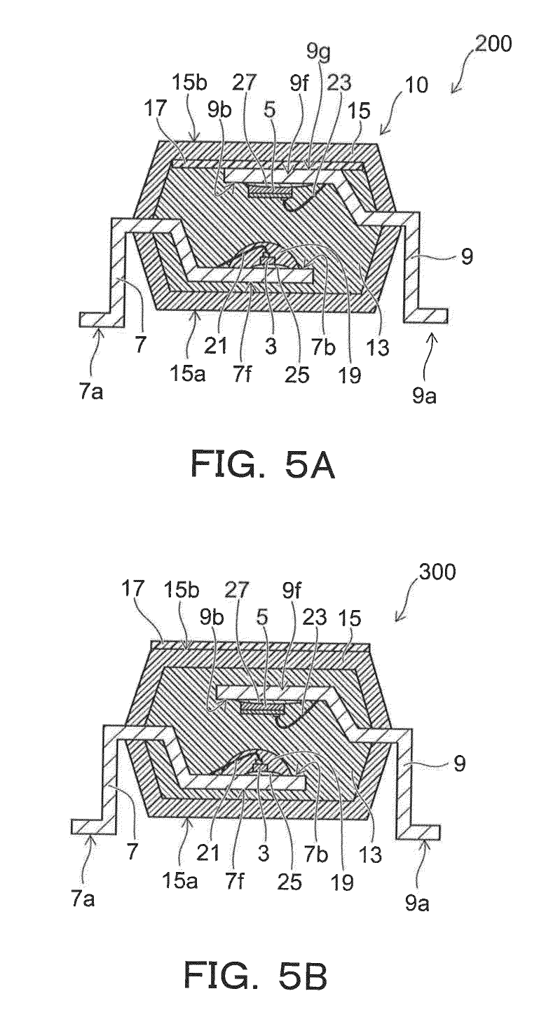

FIGS. 6A to 6C are schematic cross sectional views illustrating a semiconductor device in accordance with a second embodiment. In the embodiment, a lead 7 mounting a light-emitting element 3 and a lead 9 mounting a light-receiving element 5 are disposed side by side in a direction parallel to the upper surface of a molded body 10. Therefore, the light-emitting element 3 and the light-receiving element 5 do not face each other, and the light emitted from the light-emitting element 3 is reflected in an internal resin 13, and the light is incident upon the light-receiving element 5. The light-emitting element 3 and the light-receiving element 5 are disposed so as to face a lower surface 15a of the molded body 10.

In a semiconductor device 400 as illustrated in FIG. 6A, a light shielding layer 17 is disposed between the internal resin 13 and an external resin 15 at the side of an upper surface 15b of the molded body 10. Accordingly, the light shielding layer 17 reduces the external light incident from the upper surface 15b of the molded body 10.

The light shielding layer 17 may be provided on the entire surface of the upper surface 13b of the internal resin 13, or may be provided to cover a portion where the light-receiving element 5 is disposed.

In a semiconductor device 500 as illustrated in FIG. 6B, the light shielding layer 17 is disposed to be in contact with back surfaces 7g, 9g of the lead 7 and the lead 9 which are exposed on the upper surface of the internal resin 13. Accordingly, as compared with the semiconductor device 400 as illustrated in FIG. 6A, the height is reduced by the thickness of the internal resin 13 provided on the back surfaces of the leads 7, 9.

The light shielding layer 17 may be provided on the entire surface of the upper surface 13b of the internal resin 13, or may be provided to cover a portion where the light-receiving element 5 is disposed. However, when in contact with both of the lead 7 and the lead 9, the light shielding layer 17 is made of an insulator.

In a semiconductor device 600 as illustrated in FIG. 6C, the light shielding layer 17 is formed on the upper surface 15b of the molded body 10. For example, a metal film such as aluminum may be attached, or In or Sn may be evaporated. Then, since the light shielding layer 17 is formed after the molded body 10 is completed, manufacture of the semiconductor device 600 is easy and at a low cost.

In the second embodiment, since the light-emitting element 3 and the light-receiving element 5 do not face each other, the limitation in terms of space for ensuring the withstand voltage between the primary side and the secondary side is alleviated. The second embodiment is useful for reducing the height of the package.

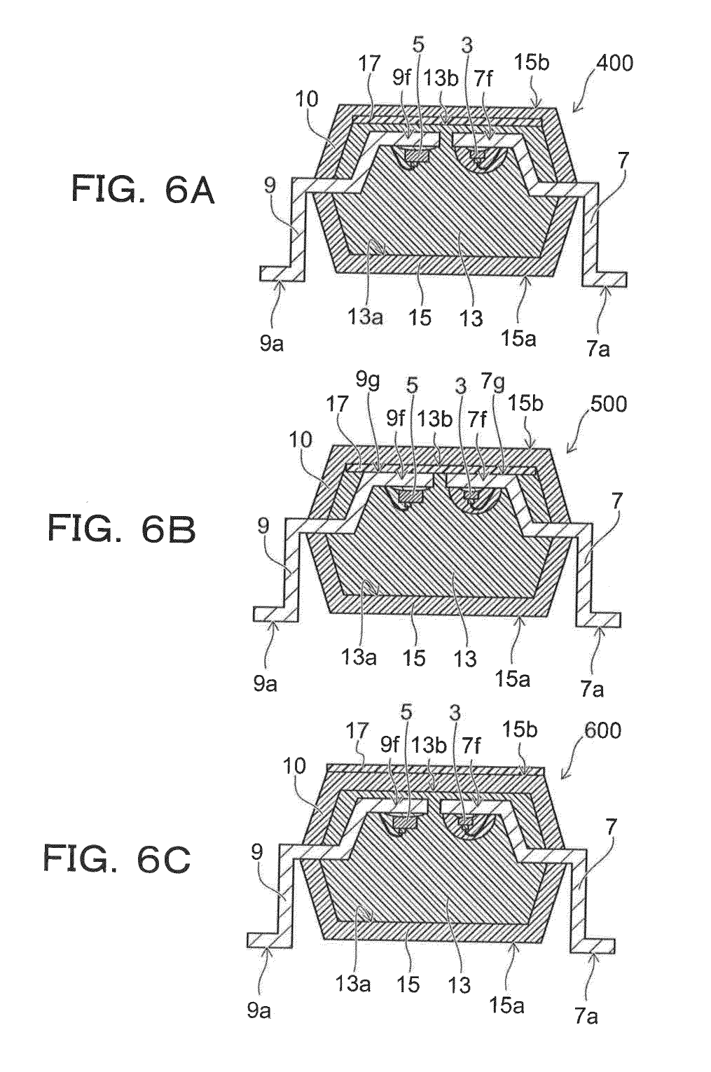

FIGS. 7A and 7B are schematic cross sectional views illustrating a semiconductor device in accordance with a modification of the second embodiment. As illustrated in FIGS. 7A and 7B, in the modification, the light-emitting element 3 and the light-receiving element 5 are disposed so as to face the upper surface 15b of the molded body 10. More specifically, the light shielding layer 17 to efficiently shield the external light is provided at the side of the upper surface 15b, so that the disposition as illustrated in FIGS. 7A and 7B is enabled.

In a semiconductor device 700 as illustrated in FIG. 7A, the light shielding layer 17 is provided between the internal resin 13 and the external resin 15. Preferably, the light shielding layer 17 is provided so as to cover the entire upper surface 13b of the internal resin 13. In a semiconductor device 800 as illustrated in FIG. 7B, the light shielding layer 17 is provided on the upper surface 15b of the molded body 10.

### Third Embodiment

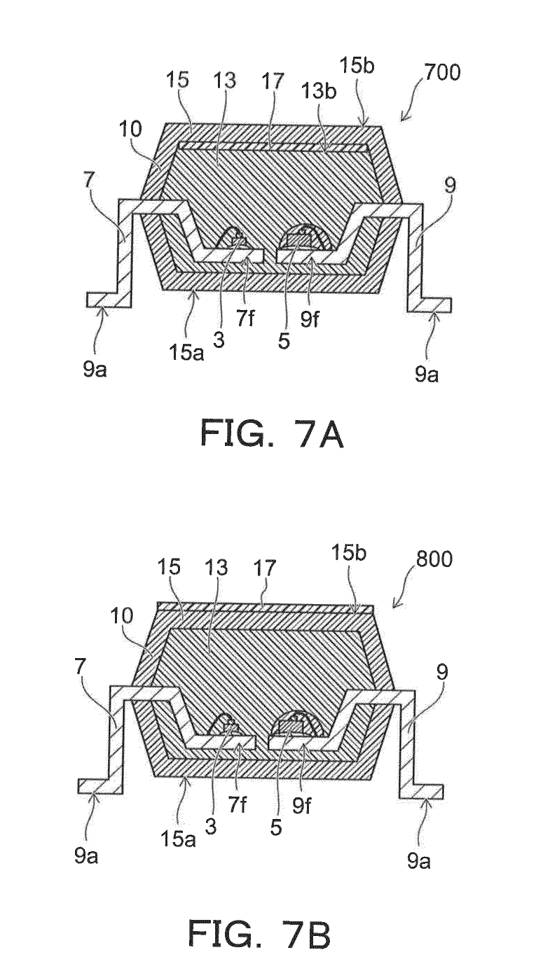

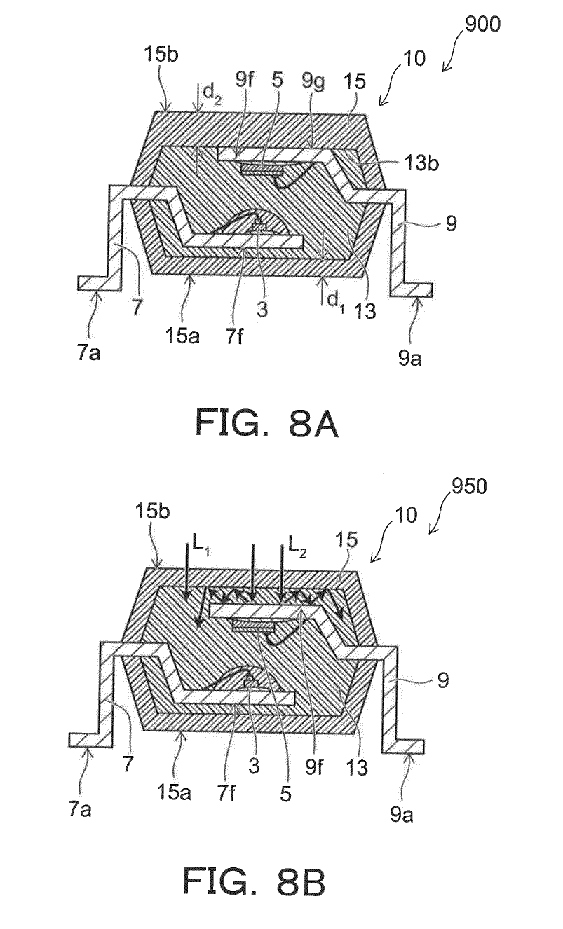

FIGS. 8A and 8B are schematic cross sectional views illustrating a semiconductor device in accordance with a third embodiment and a semiconductor device in accordance with a comparative example. FIG. 8A illustrates a semiconductor device 900 of the third embodiment. FIG. 8B illustrates a semiconductor device 950 of the comparative example.

The semiconductor device 900 is a photocoupler housing a light-emitting element 3 and a light-receiving element 5 to detect light of the light-emitting element 3 in the inside of the resin package (molded body 10). As illustrated in FIG. 8A, the light-emitting element 3 is die-bonded onto a mount bed 7f provided at a distal end of a lead 7 and is electrically connected to the lead 7. The light-receiving element 5 is die-bonded onto a mount bed 9f provided at a distal, end of a lead 9 and is electrically connected to lead 9.

The molded body 10 covers a portion where the light-emitting element 3 is connected which is a portion of the lead 7 and a portion where the light-receiving element 5 is connected which is a portion of the lead 9. The molded body 10 includes an internal resin 13 made of a transparent resin and an external resin 15 made of a light-shielding resin to shield external light. Portions of the lead 7 and the lead 9 extending from the molded body 10 are bent downward. A mounting surface 7a of the lead 7 and a mounting surface 9a of the lead 9 are in the same direction as a lower surface 15a of the molded body 10.

The light-emitting element 3 and the light-receiving element 5 are disposed so as to face each other in the molded body 10. The light-emitting surface of the light-emitting element 3 is disposed so as to face an upper surface 15b, and the light-receiving surface of the light-receiving element 5 is disposed so as to face the lower surface 15a.

In the third embodiment, a back surface 9g of the lead 9 mounting the light-receiving element 5 is exposed on the upper surface 13b of the internal resin 13, and is covered with the external resin 15. Further, a thickness d2 of the external resin 15 at the side of the upper surface 15b is thicker than a thickness d1 of the external resin 15 at the side of the lower surface 15a.

In the comparative example as illustrated in FIG. 8B, the portion of the lead 9 mounting the light-receiving element 5 is covered with the internal resin 13. External lights L1, L2 entering from the upper surface of the external resin 15 are considered. The external light L1 passes the external resin 15 without being shielded by the lead 9, and is incident upon the internal resin 13. On the other hand, originally, the external light L2 incident upon the back surface 9g of the lead 9 is shielded by the lead 9 and is not incident upon the internal resin 13, but as illustrated in FIG. 8B, reflection may be repeated within the transparent resin between the lead 9 and the external resin 15, and may be incident upon the internal resin 13. Accordingly, the dark current of the light-receiving element 5 increases with the external light L2, and the light-receiving sensitivity is reduced.

In the third embodiment, the back surface 9g of the lead 9 is exposed from the internal resin 13, and the external resin 15 is molded thereupon. Accordingly, a structure of which no transparent resin is interposed between the lead 9 and the external resin 15 is obtained. Since the external, light incident upon the back surface 9g of the lead 9 is shielded, the dark current of the light-receiving element 5 can be reduced.

Further, by increasing the thickness at the side of the upper surface of the external resin 15, the external light L1 is suppressed, and the dark current of the light-receiving element 5 is reduced, so that the light-receiving sensitivity is improved. Even when the external resin 15 at the side of the upper surface 15b is made thicker, the thickness of the molded body 10 can be maintained or made thinner by making the external resin 15 at the side of the lower surface 15a thinner.

As illustrated in FIGS. 6A to 6C, when the light-emitting element 3 and the light-receiving element 5 are disposed side by side, the back surfaces of both of the lead 7 and the lead 9 may be exposed from the internal resin 13, and the external resin 15 may be molded thereupon. When the light-receiving element 5 is disposed at the lower side, and the light-emitting element 3 is disposed at the upper side, the back surface of the lead 7 may be exposed from the internal resin 13, and the external resin 15 may be molded thereupon.

As described above, as explained using the first and second embodiments as examples, the light shielding layer 17 is provided at a position closer to the upper surface 15b of the molded body 10 than any one of the light-emitting element 3, the light-receiving element 5, the primary side lead 7, and secondary side lead 9, so that the external light is effectively shielded, and the sensitivity of the light-receiving element 5 can be improved. As explained using the third embodiment as an example, the structure is such that no transparent resin is interposed between the lead and the external resin, so that the external light is reduced, and the sensitivity of the light-receiving element 5 can be enhanced. Therefore, the semiconductor device having the thin and highly reliable package that is less likely to be affected by disturbance can be achieved.

While certain embodiments have been described, these embodiments have been presented by way of example only and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A semiconductor device, comprising:
a light-emitting element to emit light;
a light-receiving element to detect the light emitted from the light-emitting element;
a primary side lead electrically connected to the light-emitting element;
a secondary side lead electrically connected to the light-receiving element; and
a molded body to cover the light-emitting element, the light-receiving element, a portion of the primary side lead, and a portion of the secondary side lead, and including a first surface in a same direction as a mounting surface of the primary side lead and a mounting surface of the secondary side lead, and a second surface at a side opposite to the first surface,
wherein the molded body includes:
an internal resin to cover a portion fixed with the light-emitting element of the primary side lead and a portion fixed with the light-receiving element of the secondary side lead;
an external, resin to cover the internal resin, and to shield external light to which the light-receiving element is sensitive; and
a light shielding layer provided at a position closer to the second surface than any of the light-emitting element, the light-receiving element, the primary side lead, and the secondary side lead, and to shield the external light to which the light-receiving element is sensitive.

2. The semiconductor device according to claim 1, wherein the light shielding layer is provided to be in contact with a surface at a side of the second surface of at least any one of the primary side lead and the secondary side lead.

3. The semiconductor device according to claim 1, wherein the light shielding layer is provided between the internal, resin and the external, resin.

4. The semiconductor device according to claim 2, wherein the light shielding layer is provided between the internal resin and the external resin.

5. The semiconductor device according to claim 1, wherein the light shielding layer is provided on the second surface.

6. The semiconductor device according to claim 1, wherein transmittance of the external light in the light shielding layer is less than transmittance of the external light in the external resin.

7. The semiconductor device according to claim 2, wherein transmittance of the external light in the light shielding layer is less than transmittance of the external light in the external resin.

8. The semiconductor device according to claim 3, wherein transmittance of the external light in the light shielding layer is less than transmittance of the external light in the external resin.

9. The semiconductor device according to claim 5, wherein transmittance of the external light in the light shielding layer is less than transmittance of the external light in the external resin.

10. The semiconductor device according to claim 1, wherein the light shielding layer is a metal film.

11. The semiconductor device according to claim 1, wherein the light shielding layer is a resin in which optical absorption material or reflection material is dispersed.

12. The semiconductor device according to claim 1, wherein the light-emitting element and the light-receiving element are disposed so as to face each other in the molded body.

13. The semiconductor device according to claim 1, wherein the light-emitting element and the light-receiving element are disposed side by side in a direction parallel to the first surface or the second surface of the molded body.

14. A semiconductor device comprising:
a light-emitting element to emit light;
a light-receiving element to detect the light emitted from the light-emitting element;
a primary side lead connected to the light-emitting element;
a secondary side lead connected to the light-receiving element; and
a molded body to cover the light-emitting element, the light-receiving element, a portion of the primary side lead, and a portion of the secondary side lead, and including a first surface in a same direction as a mounting surface of the primary side lead and a mounting surface of the secondary side lead, and a second surface at a side opposite to the first surface,
wherein the molded body includes:
an internal resin to cover a portion fixed with the light-emitting element of the primary side lead and a portion fixed with the light-receiving element of the secondary side lead, wherein a surface at a side of the second surface of at least any of the primary side lead and the secondary side lead is exposed; and
an external resin to cover the internal resin and the surface of at least any of the primary side lead and the secondary side lead, and to shield external light to which the light-receiving element is sensitive,
wherein a thickness of the external resin at a side of the second surface is thicker than a thickness of the external resin at a side of the first surface.

15. The semiconductor device according to claim 14, wherein the light-emitting element and the light-receiving element are disposed so as to face each other in the molded body and a surface of the secondary side lead at a side of the second surface is exposed from the internal resin.

16. The semiconductor device according to claim 14, wherein the light-emitting element and the light-receiving element are disposed side by side in a direction parallel to the first surface or the second surface of the molded body, and surfaces of the primary side lead and the secondary side lead at a side of the second surface are exposed from the internal resin.

17. The semiconductor device according to claim 14, wherein the light-emitting element and the light-receiving element are disposed so as to face each other in the molded body and a surface of the primary side lead at a side of the second surface is exposed from the internal resin.
